(19) United States
(12) Patent Application Publication
(10) Pub. No.: US 2009/0201063 A1
(43) Pub. Date: Aug. 13, 2009

(54) DYNAMIC SEMICONDUCTOR DEVICE

(75) Inventors: Masahiro Nomura, Tokyo (JP); Yoshifumi Ikenaga, Tokyo (JP); Koichi Takeda, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Minato-ku (JP)

(21) Appl. No.: 12/160,071

(22) PCT Filed: Dec. 28, 2006
(86) PCT No.: PCT/JP2006/326254

§ 371 Date: Jul. 3, 2008

(30) Foreign Application Priority Data
Jan. 5, 2006 (JP) 2006-000720

(51) Int. Cl. H03K 3/289

(52) U.S. Cl. 327/202

(57) ABSTRACT

A dynamic semiconductor device is provided with a plurality of master step sections having hatch sections for temporarily storing input data and dynamic gate sections; a plurality of slave step sections, which are alternately connected with master step sections and provided with dynamic gate sections or with latch sections and dynamic gate sections; and a timing signal generating section for generating a signal for controlling operation of the master step sections and the slave step sections. The timing signal generating section supplies the latch sections with signals for storing data of the previous step before the data is erased.

### TECHNICAL FIELD

The present invention relates to a dynamic semiconductor device which is suitable for use in devices of mobile communication systems and ubiquitous communication systems which are required to provide high-speed operations with low power consumption, and more particularly, to a dynamic semiconductor device which can reduce leakage current during operation through power gating.

### BACKGROUND ART

Semiconductor devices tend to have lower threshold voltages of transistors due to a reduction in power supply voltage in connection with the miniaturization of elements, resulting in a problem of increased leakage current which flows during OFF periods. In recent years, a variety of low-power type CMOS circuits have been proposed as a technology for reducing leakage current, and a power supply switch using a low leakage element is being commercialized such as MTCMOS.

For example, FIG. 1 of Non-Patent Document 1 (S. Shigematsu, et al., “A 1-V High-Speed MTCMOS Circuit Scheme for Power-Down Application Circuits,” IEEE J. Solid-State Circuits, vol. 32, no. 6, pp. 861-869, June 1997) describes a configuration for reducing leakage current by turning off the internal power supply during standby. Non-Patent Document 1 shows that a hold circuit (FIG. 9) is provided to hold data stored in a memory even during standby.

On the other hand, FIG. 1 of Patent Document 1 (Japanese Patent Laid-Open No. 10-107613) and FIG. 1 of Patent Document 2 (Japanese Patent Laid-Open No. 10-247848) show configurations for reducing leakage current during a pre-charge period by using a low leakage element in a footer of a domino circuit which excels in speed performance.

FIG. 1 is a circuit diagram showing the configuration of a conventional dynamic semiconductor device shown in Patent Document 1. As shown in FIG. 1, the conventional dynamic semiconductor device comprises a precharge step section, a buffer step section, and a high-level holding section. The precharge step section comprises a precharge section connected in series between a first power supply (VDD) and a second power supply (ground potential), a pull down circuit network section, and a footer section. The buffer step section in turn comprises a pull-up section and a pull-down section connected in series between the first power supply (VDD) and the second power supply (ground potential).

In the dynamic semiconductor device shown in FIG. 1, the high-level holding section holds the output of the precharge step section at “1” (high level) when the output of the buffer step section is at “0” (low level). In addition, the footer section (nMOSFET) is turned of by timing signal φB when the precharge section (pMOSFET) is on, thereby reducing leakage current in the pull-down circuit network section.

Also, FIG. 10 of Non-Patent Document 2 (J. T Kao, et al., “Dual-Threshold Voltage Techniques for Low-Power Digital Circuits,” IEEE J. Solid-State Circuits, vol. 35, no. 7, pp. 1009-1018, July 2000) and FIG. 2 of Patent Document 3 (Japanese Patent No. 3580413) show a technology for solving the problem of an increase in a delay amount during operation due to the use of a low-leakage element in a footer section, while realizing a low-leakage state (a state in which a leakage current depends only on the low-leakage element) during standby by setting an input signal pattern such that a held charge is discharged during an operation standby period in a dual threshold domino circuit.

Further, FIG. 1 of Non-Patent Document 3 (S. Heo, et al., “Leakage-Biased Domino Circuits for Dynamic Fine-Grain Leakage Reduction,” 2002 Symposium on VLSI Circuits, pp. 316-319, June 2002) shows a configuration for reducing a delay amount during operation while preventing a through current from flowing in an inverter at an output stage, and for reducing leakage current during standby in a leakage biased domino circuit by turning off a power supply switch of a keeper and a GND switch of the inverter at the output stage during the standby period to naturally discharge a charge held at a dynamic node.

Further, FIG. 3 of Non-Patent Document 4 (V. Kursun, et al., “Sleep Switch Dual Threshold Voltage Domino Logic with Reduced Standby Leakage Current,” IEEE Trans. On VLSI Systems, vol. 12, no. 5. pp. 485-496, May 2004) shows a configuration for realizing a reduction in leakage current during standby while reducing a delay amount during operation by discharging a charge held at a dynamic node by a sleep switch during the standby period in a sleep switch/dual threshold domino circuit.

Further, FIG. 1 of Non-Patent Document 5 (K. S. Min, et al., “Zigzag Super Cut-off CMOS (ZSCCMOS) Block Activation with Self-Adaptive Voltage Level Controller: An Alternative to Clock-Gating Scheme in Leakage Dominant Era,” IEEE ISSCC 2003, pp. 400-401, 502, February 2003) shows a configuration, in a ZigZag technology of CMOS logic circuits for reducing leakage current during operation, for establishing a state when returning from a standby state to reduce a return time from standby by alternately providing power supply switches on one of a power supply side or a GND side of gate circuits connected at multiple stages.

However, in the semiconductor devices disclosed in the above-mentioned Patent Document 1, Patent Document 2, Non-Patent Document 1, and Non-Patent Document 5, since high-threshold transistors, which are low-leakage elements, are employed for transistors on critical paths which are required to perform high-speed operations, a problem arises in which a large amount of delay occurs during operation.

On the other hand, in the semiconductor devices disclosed in the above-mentioned Patent Document 3, Non-Patent Document 2, Non-Patent Document 3, Non-Patent Document 4, and Non-Patent Document 5, since a standby signal is used for power gating for reducing leakage current during operation, a problem arises that the size of a control circuit is increased. When power gating using a clock enable signal, for example, is applied to the dynamic semiconductor devices disclosed in Patent Document 3, Non-Patent Document 2, Non-Patent Document 3, and Non-Patent Document 4 in order to solve such a problem of an increased circuit scale, an attempt to easily exercise control by using the clock enable signal results in a loss of the stage of a dynamic node in a standby mode in the latch section of the master step section, as shown in FIG. 2, even if the supply of the clock is resumed. For this reason, when a transition is made to the standby mode using the clock enable signal, a problem arises in that a malfunction occurs.

### DISCLOSURE OF THE INVENTION

It is therefore an object of the present invention to provide a dynamic semiconductor device which is capable of reducing leakage current during operation by applying power gating which uses a clock enable signal, and which is capable of reducing delay amount during operation.

To achieve the above object, a dynamic semiconductor device is provided with a plurality of master step sections each comprising a latch section for temporarily storing input data and a dynamic gate section applied with a timing signal different from the latch section; a plurality of slave step sections, which are alternately connected with master step sections and provided with dynamic gate sections or with latch sections and dynamic gate sections; and a timing signal generating section for generating a signal for controlling operation of the master step sections and the slave step sections. The timing signal generating section supplies the latch sections with signals for storing data of the previous step before the data is erased.

In the configuration as described above, since the latch section holds data at the previous stage before the data is erased, it is not necessary to place transistors having a high threshold, which are low-leakage elements, or surplus gates on a critical path which is required to perform high-speed operations. Consequently, the resulting dynamic semiconductor device reduces a delay amount during operation.

Also, by utilizing the clock enable signal for the power gating for reducing leakage current during operation, a standby signal need not be added for the power gating, as in a conventional dynamic semiconductor device, thus providing a dynamic semiconductor device which has a control circuit in a small scale.

### BRIEF DESCRIPTION OF THE DRAWINGS

FIG. 1 is a circuit diagram showing the configuration of a conventional dynamic gate section.

FIG. 2 is a timing chart showing the operation of a conventional dynamic semiconductor device.

FIG. 3 is a block diagram showing the configuration of a first embodiment of a dynamic semiconductor device of the present invention.

FIG. 4 is a block diagram showing an exemplary configuration of a dynamic gate section shown in FIG. 3.

FIG. 5 is a block diagram showing an exemplary configuration of a slave section shown in FIG. 3.

FIG. 6 is a circuit diagram showing an exemplary configuration of a timing signal generating section shown in FIG. 3.

FIG. 7 is a timing chart showing the operation of the first embodiment of the dynamic semiconductor device of the present invention.

FIG. 8 is a block diagram showing the configuration of a second embodiment of a dynamic semiconductor device of the present invention.

FIG. 9 is a block diagram showing the configuration of a third embodiment of a dynamic semiconductor device of the present invention.

FIG. 10 is a block diagram showing the configuration of a fourth embodiment of a dynamic semiconductor device of the present invention.

FIG. 11 is a circuit diagram showing a specific example of the dynamic gate section shown in FIG. 4.

FIG. 12 is a block diagram showing another exemplary configuration of the dynamic gate section shown in FIG. 3.

FIG. 13 is a circuit diagram showing a specific example of a dynamic gate section shown in FIG. 12.

FIG. 14 is a circuit diagram showing another specific example of the dynamic gate section shown in FIG. 12.

FIG. 15 is a block diagram showing another exemplary configuration of the dynamic gate section shown in FIG. 3.

FIG. 16 is a circuit diagram showing a specific example of the dynamic gate section shown in FIG. 15.

FIG. 17 is a block diagram showing another exemplary configuration of the dynamic gate section shown in FIG. 3.

FIG. 18 is a block diagram showing another exemplary configuration of the dynamic gate section shown in FIG. 3.

FIG. 19 is a block diagram showing another exemplary configuration of the dynamic gate section shown in FIG. 3.

FIG. 20 is a block diagram showing another specific example of the dynamic gate section shown in FIG. 3.

FIG. 21 is a circuit diagram showing a specific example of a precharge step section which comprises a footer section shown in FIG. 20.

FIG. 22 is a circuit diagram showing another specific example of the precharge step section which comprises the footer section shown in FIG. 20.

FIG. 23 is a circuit diagram showing another specific example of the precharge step section which comprises the footer section shown in FIG. 20.

FIG. 24 is a block diagram showing another exemplary configuration of the dynamic gate section shown in FIG. 3.

FIG. 25 is a circuit diagram showing a specific example of a dynamic gate section shown in FIG. 23.

FIG. 26 is a circuit diagram showing another specific example of the dynamic gate section shown in FIG. 24.

FIG. 27 is a block diagram showing another exemplary configuration of the dynamic gate section shown in FIG. 3.

FIG. 28 is a circuit diagram showing a specific example of the dynamic gate section shown in FIG. 27.

FIG. 29 is a block diagram showing another exemplary configuration of the dynamic gate section shown in FIG. 3.

FIG. 30 is a circuit diagram showing a specific example of the dynamic gate section shown in FIG. 29.

FIG. 31 is a block diagram showing another exemplary configuration of a latch section shown in FIG. 3.

FIG. 32 is a block diagram showing another exemplary configuration of the latch section shown in FIG. 3.

FIG. 33 is a block diagram showing another exemplary configuration of the timing signal generating section shown in FIG. 3.

FIG. 34 is a circuit diagram showing a specific example of a low pass section shown in FIG. 33.

FIG. 35 is a timing chart showing the operation of the low pass section shown n FIG. 34.

FIG. 36 is a circuit diagram showing another specific example of the low pass section shown in FIG. 33.

FIG. 37 is a circuit diagram showing a specific example of the low pass section shown in FIG. 33.

FIG. 38 is a block diagram showing another exemplary configuration of the timing signal generating circuit shown in FIG. 3.

FIG. 39 is a timing chart showing the operation of a dynamic semiconductor device which comprises the timing signal generating section shown in FIG. 38.

FIG. 40 is a block diagram showing another exemplary configuration of the timing signal generating section shown in FIG. 3.

FIG. 41 is a timing chart showing the operation of a dynamic semiconductor device which comprises the timing signal generating section shown in FIG. 40.

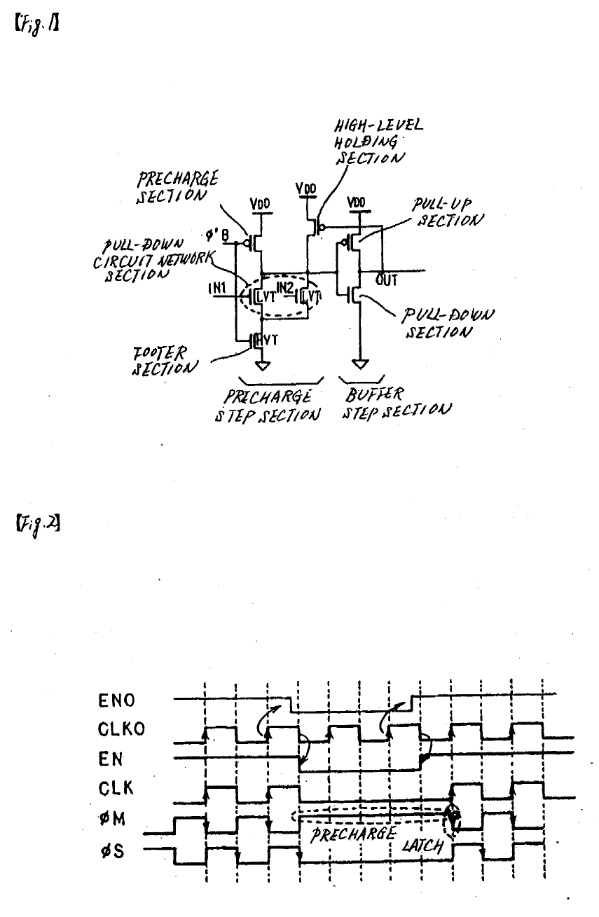

### BEST MODE FOR CARRYING OUT THE INVENTION

Next, the present invention will be described with reference to the drawings.

### First Embodiment

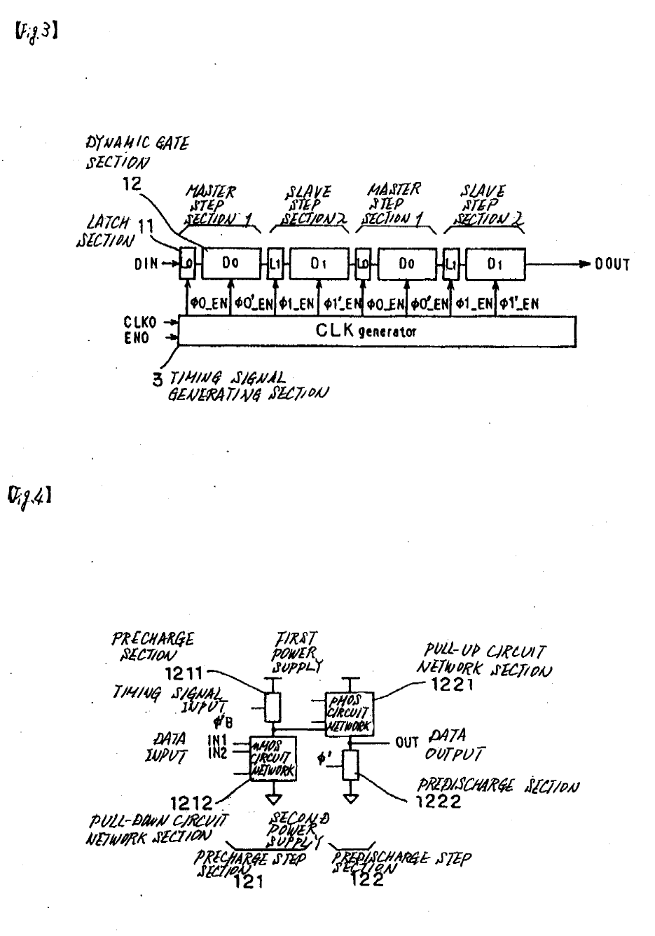

FIG. 3 is a block diagram showing the configuration of a first embodiment of a dynamic semiconductor device of the present invention.

As shown in FIG. 3, the dynamic semiconductor device of the first embodiment comprises master step section 1, slave step section 2, and timing signal generating section 3.

Master step section 1 and slave step section 2 comprise latch section 11 and dynamic gate section 12, respectively. Master step section 1 and slave step section 2 are connected in cascade, and in the first embodiment, one master step section 1 and one slave step section 2 form a pipeline stage for executing required logical operations. In the dynamic semiconductor device of the first embodiment, a plurality of pipeline stages are connected in cascade, where a predetermined logical operation is repeatedly executed in each pipeline stage. Timing signal generating section 3 is supplied with clock CLK0 and clock enable signal EN0, and outputs a timing signal for controlling the operation of each of master step section 1 and slave step section 2.

As shown in FIG. 4, dynamic gate section 12 comprises precharge step section 121 and predischarge step section 122. Precharge step section 121 comprises precharge section 1211 which turns on or off in accordance with a timing signal (φ′B), and pull-down circuit network section 1212 for outputting a logical operation result of input data (IN1, IN2), and is arranged in series between a first power supply and a second power supply. In this regard, a first power supply voltage and a second power supply voltage are in a relationship of First Power Supply Voltage>Second Power Supply Voltage, where the first power supply is, for example, VDD, and the second power supply is a ground potential. Predischarge step section 122 in turn comprises pull-up circuit network section 1221 for outputting a logical operation result of data output from the precharge step section, and predischarge section 1222 which turns on or off in accordance with a timing signal (φ′), and is arranged in series between the first power supply and the second power supply. Precharge step sections 121 and predischarge step sections 122 may be alternately connected at a plurality of stages. Low-leakage elements are employed for precharge section 1211 and predischarge section 1222, while high-speed elements are employed for pull-down circuit network section 1212 and pull-up section 1221.

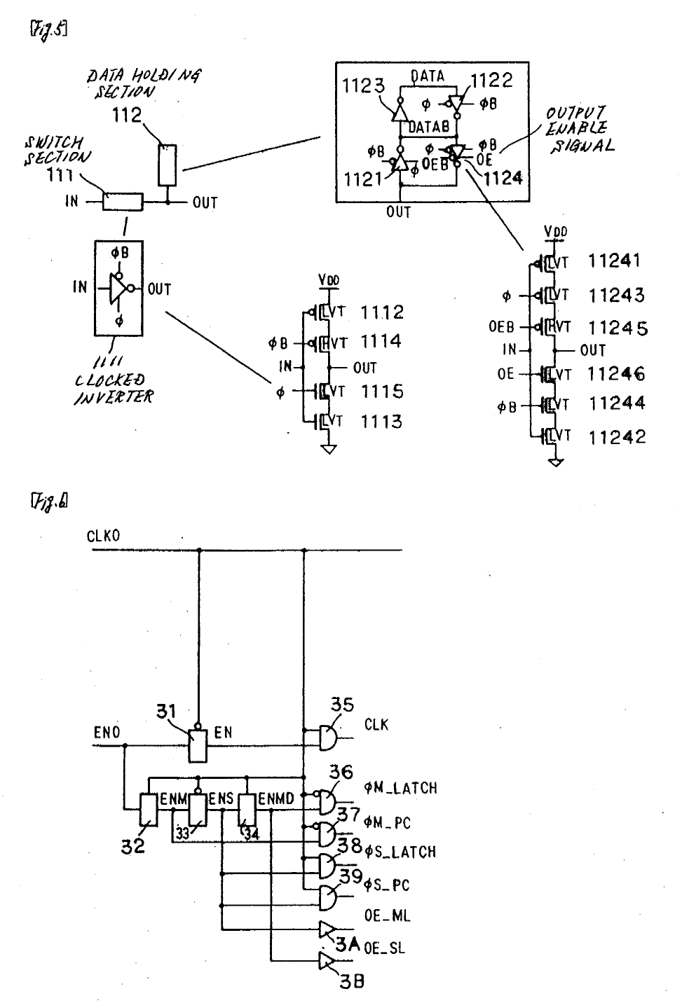

As shown in FIG. 5, latch section 11 comprises switch section 111 and data holding section 112. Switch section 111 is arranged between input and output terminals (between IN and OUT), while data holding section 112 is connected to an output terminal. Data holding section 112 latches input data when switch section 111 turns on, and continues to hold the data when switch section 111 turns off.

Switch section 111 comprises clocked inverter 1111 which is controlled ON/OFF to output data by timing signals (φ, φB) at a predetermined period, and is supplied with the first power supply voltage and second power supply voltage, respectively. Clocked inverter 1111 comprises transistors 1112, 1113, 1114 and 1115 connected in series, where a data input signal (IN) is supplied to gate terminals of transistors 1112, 1113 closer to the power supply, and the timing signals (φ, φB) are supplied to gate terminals of transistors 1114, 1115 closer to the output terminal, respectively. A low-leakage element is employed for transistor (pull-up transistor) 1114 closer to the first power supply, supplied with the timing signal, while high-speed elements are employed for other transistors 1112, 1113, 1115.

Data holding section 112 comprises inverter 1123 and clocked inverter 1122 having their input terminals and output terminals connected to each other, and clocked inverter 1121 and clocked enabled inverter 1124 having their input terminals and output terminals connected to each other, where each of the inverters is supplied with the first power supply voltage and second power supply voltage, respectively. Clocked enabled inverter 1124 is controlled ON/OFF to output data with a timing signal and an enable signal synchronized with the supply/stop of the clock and used for power gating.

Clocked enabled inverter 1124 comprises transistors 11241-11246 connected in series, and supplied with output enable signals (OE, OEB), timing signals (φ, φB), and data input signal (IN) in the sequence from the transistor closest to the output terminal to the transistor closest to the power supply. Low-leakage elements are employed for the transistors included in data holding section 112 except for some transistors included in clocked enabled inverters 1124.

As shown in FIG. 6, timing signal generating section 3 comprises low through latch circuit 31, low through latch circuit 33, high through latch circuit 32, high through latch circuit 34, 2-input AND circuits 35-39, and buffers 3A-3B. One of two input terminals of 2-input AND circuits 36, 37 is an inverting input terminal, and clock CLK0 is applied to the inverting input terminal.

Low through latch circuit 31, low through latch circuit 33, high through latch circuit 32, and high through latch circuit 34 are respectively, supplied with clock CLK0. High through latch circuit 32, low through latch circuit 33, and high through latch circuit 34 are connected in series, and an input terminal of high through latch circuit 32 is applied with clock enable signal EN0. An input terminal of low through latch circuit 31 is also applied with clock enable signal EN0.

2-input AND circuit 35 receives the output signal of low through latch circuit 31 and clock CLK0, and outputs gated clock CLK. 2-input AND circuit 36 receives output signal ENMD of high through latch circuit 34 and clock CLK0, and outputs master step latch timing signal φM_LATCH. 2-input AND circuit 37 receives output signal ENM of high through latch circuit 32 and clock CLK0, and outputs master step precharge timing signal φM_PC. 2-input AND circuit 38 receives output signal ENS of low through latch circuit 33 and clock CLK0, and outputs slave step latch timing signal φS_LATCH. 2-input AND circuit 39 receives output signal ENS of low through latch circuit 33 and clock CLK0, and outputs slave step precharge timing signal φS_PC. Buffer 3A receives output signal ENS of low through latch circuit 33, and outputs as master step latch hold data output enable signal OE_mL. Buffer 3B in turn receives output signal ENMD of high through latch circuit 34 and outputs as slave step latch hold data output enable signal OE_SL. Low-leakage elements are employed for all transistors included in timing signal generating section 3.

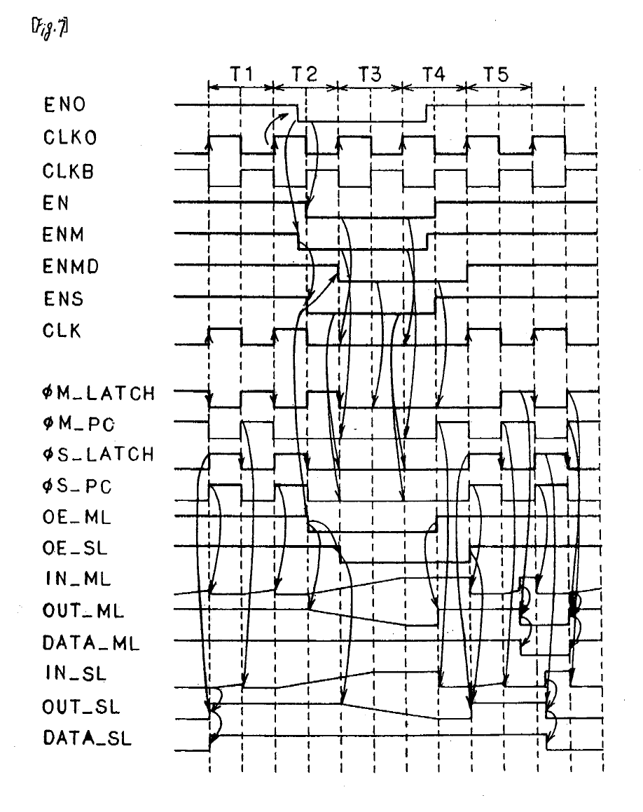

Next, the operation of the dynamic semiconductor device of the first embodiment will be described with reference to the timing chart of FIG. 7.

As shown in FIG. 6, gated clock CLK, master step latch timing signal φM_LATCH, master step precharge timing signal φM_PC, slave step latch timing signal φS_LATCH, and slave step precharge timing signal φS_PC are gated by clock enable signal EN, master step clock enable signal ENM, slave step clock enable signal ENS, or master step one-cycle delayed clock enable signal ENMD.

Input signal (output signal from slave step section 2) IN_ML to master step section 1, output signal OUT_ML from master step section 1, data DATA_ML held by the latch section of master step section 1, input signal (output from master step section 1) IN_SL to slave step section 2, output signal OUT_SL from the latch section of slave step section 2, data DATA_SL held by the latch section of slave step section 2 are controlled by the aforementioned gated clock CLK, master step latch timing signal φM_LATCH, master step precharge timing signal φM_PC, slave step latch timing signal φS_LATCH and slave step precharge timing signal φS_PC, and master step latch hold data output enable signal OE_ML and slave step latch hold data output enable signal OE_SL.

As shown in FIG. 7, clock enable signal EN0, for example, changes to 1 (significant value, here, high level) in period T1, changes from 1 to 0 (here, low level) in period T2, stays at 0 in period T3, changes from 0 to 1 in period T4, and stays at 1 in period T5. In this event, assume that clock enable signal EN0 changes in the former half of the period. As such, when clock enable signal EN0 changes from 1 to 0, the supply of gated clock CLK is stopped in the next period. On the other hand, when clock enable signal EN changes from 0 to 1, the supply of gated clock CLK is resumed in the next period. FIG. 7 shows an example in which gated clock CLK stops in periods T3, T4, resulting in a transition of the signal level to 0. Timing signal generating section 3 generates a signal for latch section 11 of master step section 1 to transition to a clock stop state after it has held data. Also, timing signal generating section 3 generates a signal for outputting data held in latch section 11 of master step section 1 and for turning on precharge section 1211 and predischarge section 1222 of dynamic gate section 12 of master step section 1 when clock enable signal transitions to 1.

Master step section 1 performs a precharge in the latter half of each period in accordance with master step precharge timing signal φM_PC, and latches output data of slave step section 2 disposed at the previous stage at a change of period in accordance with master step latch timing signal φM_LATCH. In this event, master step latch timing signal φM_LATCH for latching input data is a signal which is delayed by one cycle of clock CLK0 from master step precharge timing signal φM_PC for turning on (precharging) the precharge section of master step section 1. Accordingly, necessary data is all held by latch section 11 before the data is erased, and can be normally returned from a low leakage state. Consequently, the resulting dynamic semiconductor device is free from malfunctions.

Notably, master step section 1 stops the precharge operation in the latter half of period T2 and period T3 in accordance with master step precharge timing signal φM_PC. Also, since gated clock CLK stops in period T3 and period T4, master step section 1 does not perform the latch operation at the boundary of period T3 and period T4 and at the boundary of period T4 and period T5 with master step latch timing signal φM_LATCH.

On the other hand, slave step section 2 performs a precharge in the former half of each period in accordance with slave step precharge timing signal φS_PC, and latches output data of master step section 1 at the previous stage at the middle of each period in accordance with slave step latch timing signal φS_LATCH.

Notably, slave step section 2 stops the precharge in the former half of period T3 and period T4 in accordance with slave step precharge timing signal φS_PC. Also, since gated clock CLK stops from the latter half of period T2 to the former half of period T4, slave step section 2 does not perform the latch operation at falling edges of period T3 and period T4 in accordance with slave step latch timing signal φS_LATCH.

Master step latch hold data output enable signal OE_ML and slave step latch hold data output enable signal OE_SL are not output for the duration from the latter half of period T2 to the former half of period T4 and for the duration of period T3 and period T4. In this regard, in order to reduce the number of control lines, it is also possible to share master step latch hold data output enable signal OE_ML and slave step latch hold data output enable signal OE_SL. In this event, slave step clock enable signal ENS and output signal ENMD of high through latch circuit 34 may be logically ORed to stop the output in the former half of period T3 and period T4.

As master step section 1 and slave step section 2 terminate the precharge (or predischarge), a held charge at the dynamic node is discharged (or charged), causing a gradual increase in the voltage level of input signal IN_ML to master step section 1 and the voltage level of input signal IN_SL to slave step section 2. When the precharge (or predischarge) stops, the discharge (or charge) further advances, and a low-power state is reached when the discharge (charge) is completed.

On the other hand, held data output from master step section 1 and slave step section 2 are stopped, held charges at the latch nodes of output signal OUT_ML of master step section 1 and output signal OUT_SL of slave step section 2 are discharged (charged), and a low-power state is reached when the discharge (charge) is completed. In this event, since the held data is stored in data holding section 112 which is comprised of low-leakage elements, the held data will never be affected by power gating which uses the clock enable signal.

The held data output from master step section 1 is stopped from the latter half of period T2 to the former half of period T4. On the other hand, the held data output from slave step section 2 is stopped in period T3 and period T4. As the output of the held data is resumed, output signal OUT_ML of master step section 1 and output signal OUT_SL of slave step section 2 return from a discharge (charge) state to a hold data level.

According to the dynamic semiconductor device of this embodiment, since the latch section holds data at the previous stage before it is erased, transistors having high thresholds, which are low-leakage elements, and surplus gates need not be placed on a critical path which is required to perform high-speed operations. Consequently, the resulting dynamic semiconductor device experiences a shorter delay amount during operation.

Also, by utilizing a clock enable signal for power gating for reducing leakage current during operation, it is not necessary to add a standby signal for the power gating, as has been required in the conventional dynamic semiconductor device, so that the resulting dynamic semiconductor device has a control circuit that has a smaller scale.

### Second Embodiment

Next, a second embodiment of a dynamic semiconductor device of the present invention will be described with reference to the drawings.

FIG. 8 is a block diagram showing the configuration of the second embodiment of the dynamic semiconductor device of the present invention.

The first embodiment has shown an example in which one pipeline stage is comprised of one master step section and one slave step section. In the dynamic semiconductor device of the second embodiment, one pipeline stage comprises one master step section and a plurality of slave step sections.

In such a configuration, timing signal generating section 3 does not generate a two-phase timing signal for master step section 1 and slave step section 2, but generates a multi-phase timing signal which has the number of phases equal to the number of slave step sections plus one. The rest of the configuration is similar to the first embodiment, so that a description thereon is omitted. In such a configuration, effects can also be produced in a manner similar to the first embodiment.

### Third Embodiment

Next, a third embodiment of a dynamic semiconductor device of the present invention will be described with reference to the drawings.

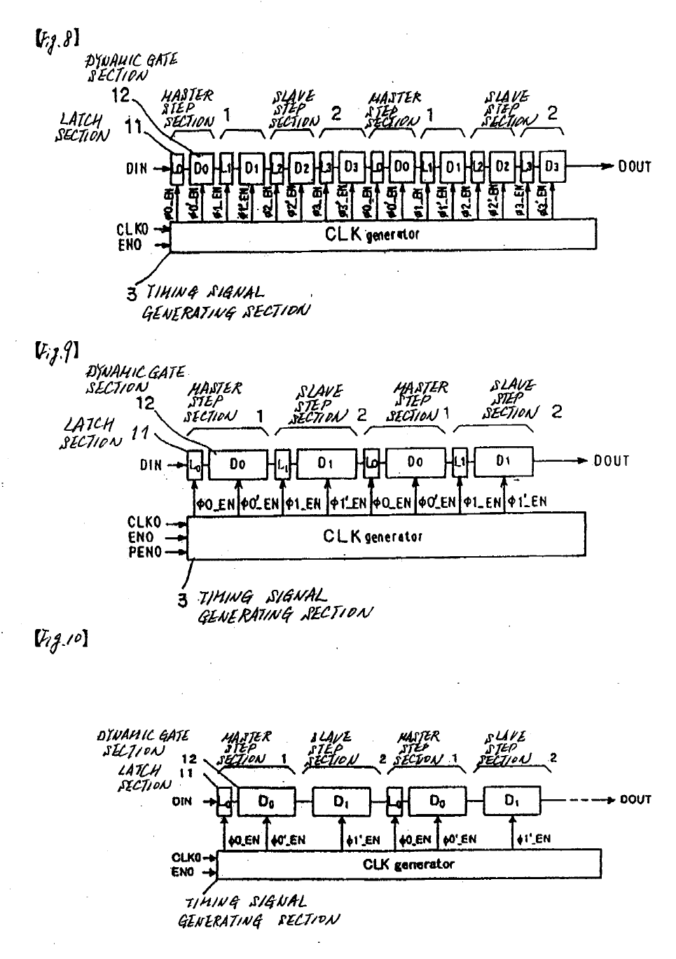

FIG. 9 is a block diagram showing the configuration of the third embodiment of the dynamic semiconductor device of the present invention.

In the first embodiment, timing signal generating section 3 is applied with clock CLK0 and clock enable signal EN0. In the dynamic semiconductor device of the third embodiment, timing signal generating section 3 is also applied with power supply enable signal input PEN0 in addition to clock CLK0 and clock enable signal EN0.

Power supply enable signal input PEN0 is utilized, for example, for an output enable control of data held in the latch section, a level hold enable control when having a level holding section for holding a precharge (predischarge) level of a dynamic node, a pull-down (pull-up) control when having a pull-down (pull-up) section for discharging (supplying) the precharge (predischarge) level of the dynamic node for transition to a low-leakage state, and the like. The rest of the configuration is similar to the first embodiment, so that a description thereon is omitted. In such a configuration, effects can also be produced in a manner similar to the first embodiment.

### Fourth Embodiment

Next, a fourth embodiment of a dynamic semiconductor device of the present invention will be described with reference to the drawings.

FIG. 10 is a block diagram showing the configuration of the fourth embodiment of the dynamic semiconductor device of the present invention.

The first embodiment has shown a configuration in which latch section 11 is included in master step section 1 and slave step section 2, respectively. The dynamic semiconductor device of the fourth embodiment omits latch section 11 of slave step section 2 from the configuration shown in the first embodiment.

When power gating is performed using a clock enable signal over one clock cycle or more, latch section 11 for holding data may be provided only in master step section 1. With the employment of a configuration which does not comprise a latch section in slave step section 2, a well-known skew tolerant design can be made. In such a configuration, effects can also be produced in a manner similar to the first embodiment.

### EXAMPLES

Next, examples of the dynamic semiconductor devices of the present invention will be described with reference to the drawings.

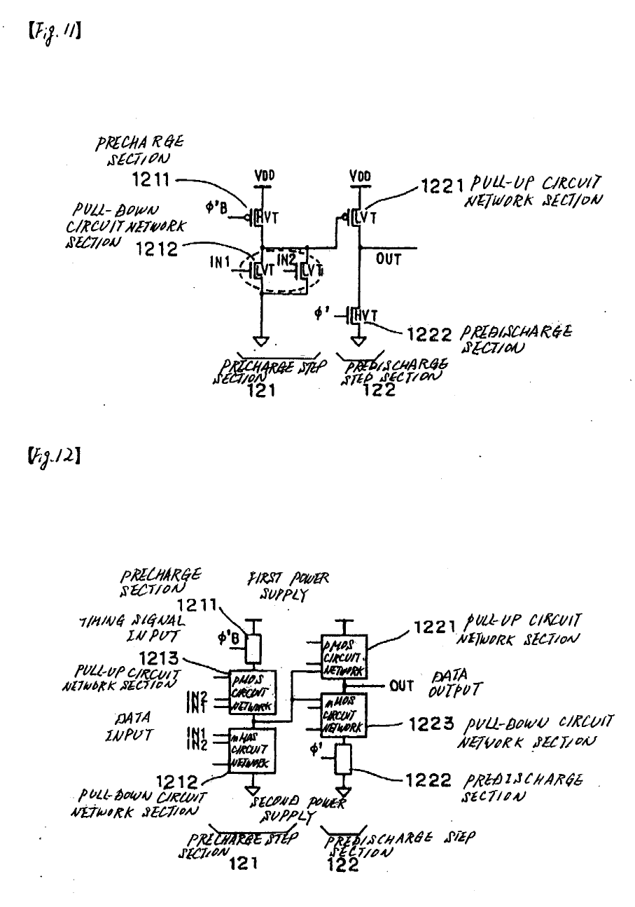

In the following, specific examples of circuits which can be applied to the dynamic semiconductor devices shown in the aforementioned first to fourth embodiments will be shown with reference to FIGS. 11-41. In this regard, the examples will additionally present exemplary modifications to the dynamic semiconductor devices shown in the aforementioned first to fourth embodiments.

As shown in FIG. 11, precharge step section 121 shown in FIG. 4 is such that a low-leakage element pMOSFET can be employed for precharge section 1211, and a high-speed element nMOSFET can be employed for pull-down circuit network section 1212. Also, predischarge step section 122 is such that a high-speed element pMOSFET can be employed for pull-up circuit network section 1221, and a low-leakage element nMOSFET can be employed for predischarge section 1222. In this regard, in FIG. 4, “HVT” is described because a transistor having a relatively high threshold voltage is employed as a low-leakage element, while “LVT” is described because a transistor having a relatively low threshold voltage is employed for a high-speed element. Assume that, in the following description, as well, a transistor having a relatively high threshold voltage is employed for a low-leakage element, and a transistor having a relatively low threshold voltage is employed for a high-speed element unless otherwise described, in particular.

As shown in FIG. 12, precharge step section 121 shown in FIG. 4 may comprise pull-up circuit network section 1213 for outputting a logical operation result of input data between precharge section 1211 and pull-down circuit network section 1212. Predischarge step section 122 in turn may comprise pull-down circuit network section 1223 for outputting a logical operation result of data output from the precharge step section between pull-up circuit network section 1221 and predischarge section 1222.

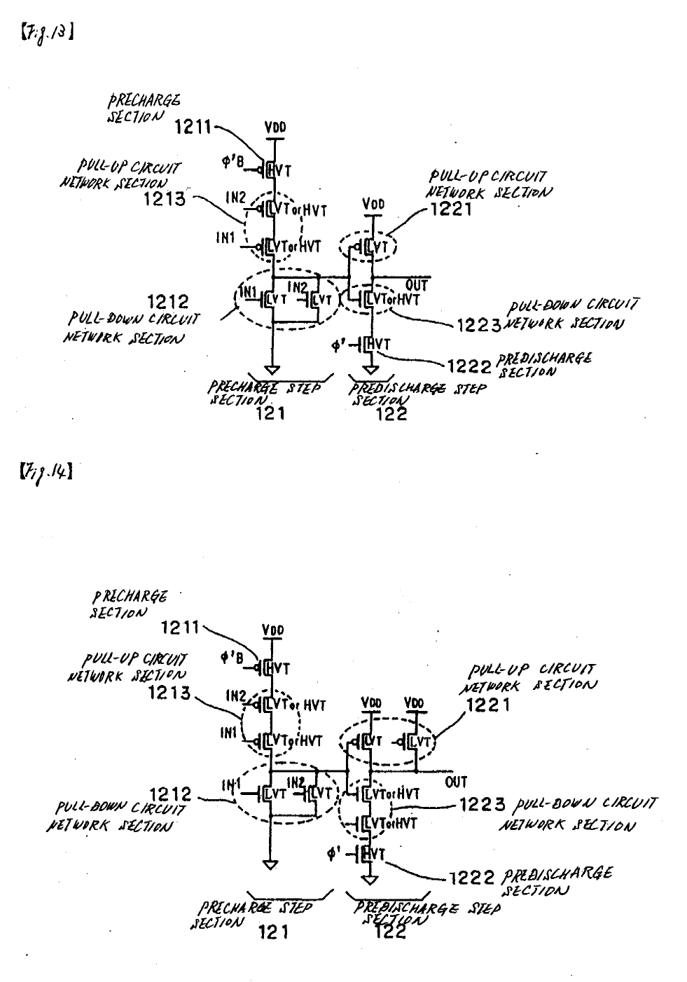

Here, precharge step section 121 shown in FIG. 12 is such that, as shown in FIGS. 13 and 14, a low-leakage element pMOSFET can be employed for precharge section 1211, a low leakage element or a high speed element pMOSFET can be employed for pull-up circuit network section 1213, and a high-speed element nMOSFET can be employed for pull-down circuit network section 1212.

Predischarge step section 122 is such that a high-speed pMOSFET may be employed for pull-up circuit network section 1221, a low-leakage element or a high-speed element nMOSFET may be employed for pull-down circuit network section 1223, and a low-leakage element nMOSFET may be employed for predischarge section 1222.

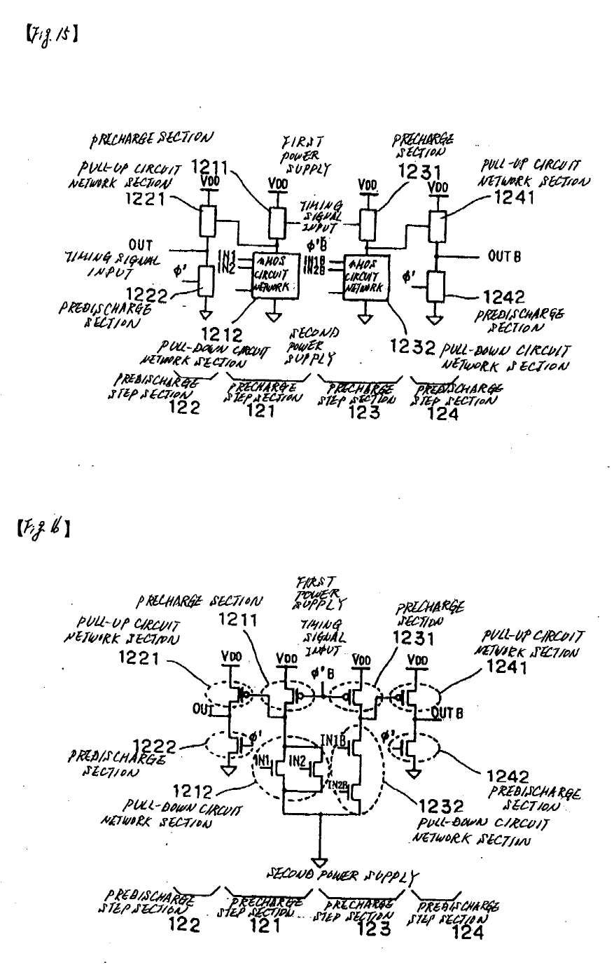

As shown in FIG. 15, dynamic gate section 12 comprises two precharge step sections 121, 123 and two predischarge step sections 122, 124, and may be in a differential circuit configuration in which each precharge step section and predischarge step section are applied with a timing signal and two complementary data signals, respectively. While FIG. 15 shows an example which comprises two sets of the precharge step sections and predischarge step sections shown in FIG. 4, it may comprise two sets of the precharge step sections and predischarge step sections shown in FIG. 12, respectively, and may be in a differential circuit configuration in which each precharge step section and predischarge step section are applied with a timing signal and two complementary data signals, respectively.

As shown in FIG. 16, two precharge step sections 121, 123 shown in FIG. 15 are such that low-leakage elements pMOSFETs can be employed for precharge sections 1211, 1231, respectively, and high-speed elements nMOSFETs can be employed for pull-down circuit network sections 1212, 1232. Pull-down circuit network section 1212 has two nMOSFETs connected in parallel, while pull-down circuit network section 1232 has two nMOSFETs connected in series. Two predischarge step network sections 122, 124 are similar in configuration to the predischarge step section shown in FIG. 11.

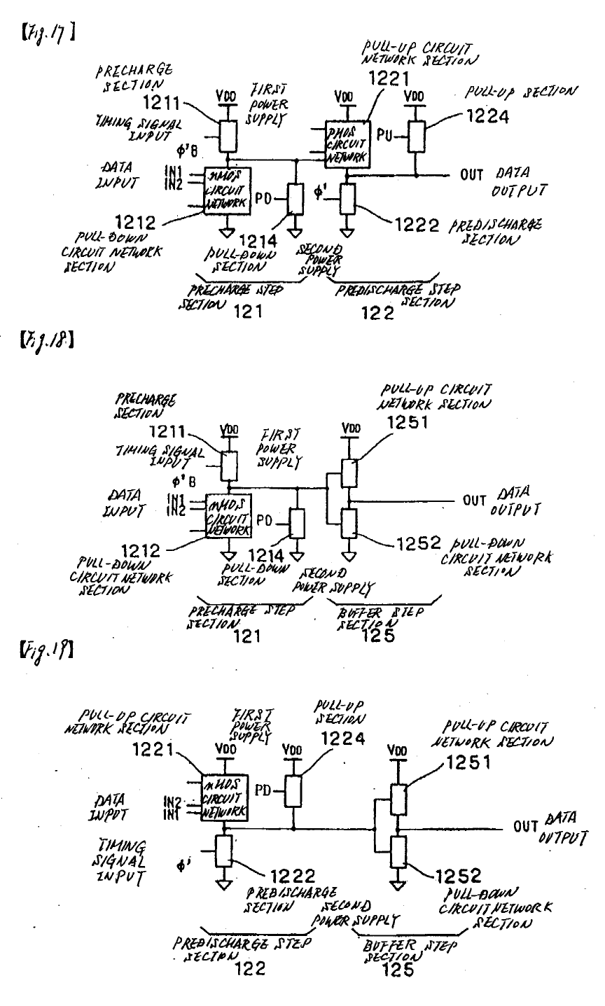

As shown in FIG. 17, dynamic gate section 12 comprises pull-down section 1214 for pulling an output terminal of precharge step section 121 down to the second power supply, and may comprise pull-up section 1224 for pulling an output terminal of predischarge step section 122 up to the first power supply. In this regard, dynamic gate section 12 may comprise pull-down section 1214 and pull-up section 1224, respectively, or may comprise either pull down section 1214 or pull-up section 1224.

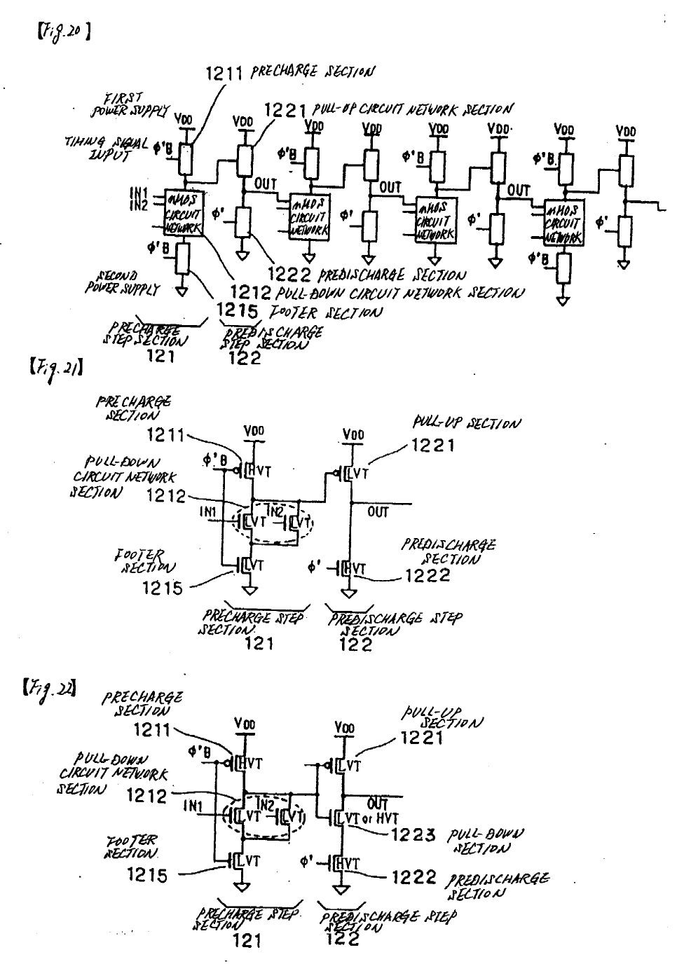

Also, dynamic gate section 12 may be configured with predischarge step section of dynamic gate section 12 as shown in FIG. 17 replaced with buffer step section (inverter) 125 which comprises pull-up circuit network section 1251 and pull-down circuit network section 1252, as shown in FIG. 18. Also, dynamic gate section 12 may comprise predischarge step section 122 of dynamic gate section 12 shown in FIG. 17 at the first stage, and buffer step section (inverter) 125 comprised of pull-up section 1224 and pull-up circuit network section 1251 and pull-down circuit network section 1252 at the output, as shown in FIG. 19.

While FIG. 17 shows an example which comprises pull-down section 1214 at the output of the precharge step section shown in FIG. 4, and pull-up section 1224 at the output of predischarge step section 122 shown in FIG. 4, pull-down section 1214 may be connected to the output terminal of the precharge step section shown in FIG. 12 or FIG. 15, and pull-up section 1224 may be connected to the output terminal of the predischarge step section shown in FIG. 12 or FIG. 15.

Also, while FIG. 18 shows an example which comprises pull-down section 1214 and an inverter at the output of the precharge step section shown in FIG. 4, and FIG. 19 shows an example which comprises pull-up section 1224 and an inverter at the output of the predischarge step section shown in FIG. 4, pull-down section 1214 and an inverter may be provided at the output of the precharge step section shown in FIG. 12 or FIG. 15, and pull-up section 1224 and an inverter may be provided at the output of the predischarge step section shown in FIG. 12 or FIG. 15.

Also, dynamic gate section 12 may comprise a plurality of precharge step sections 121 and a plurality of predischarge step sections 122 which are alternately connected at a plurality of stages, as shown in FIG. 20. In this event, precharge step section 121 may be provided, every arbitrary number of steps, with footer section 1215 which is a switch for turning off the power supply voltage (second power supply voltage) supplied to pull-down circuit network section 1212 during a precharge, and predischarge step section 122 may be provided with a header section which is a switch for turning off the power supply voltage supplied to pull-up circuit network section 1221 during a predischarge. For reference, FIG. 20 only shows the configuration which comprises footer section 1215 in precharge step section 121.

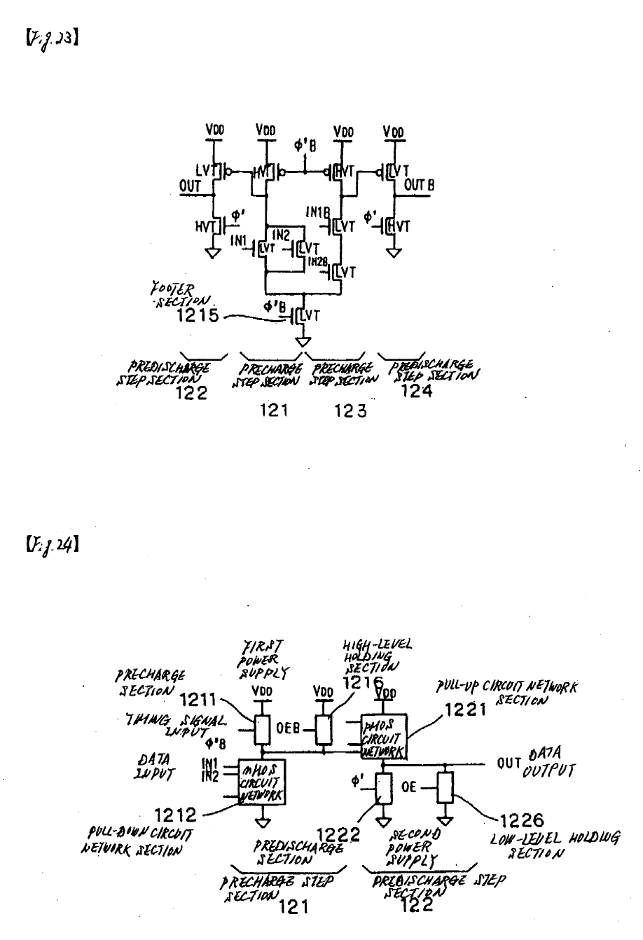

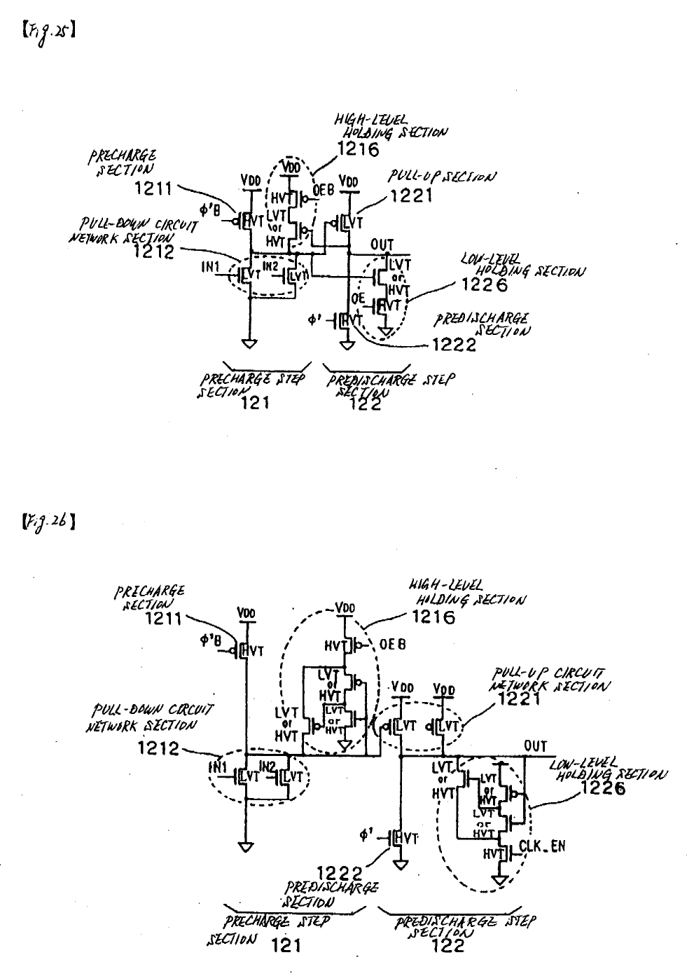

As shown in FIGS. 21, 22 and 23, high-speed elements nMOSFETS can be employed in footer section 1215 which is contained in the dynamic gate section shown in FIG. 20. FIG. 21 is an example which comprises footer section 1215 in the precharge step section shown in FIG. 11, and FIG. 22 is an example which comprises footer section 1215 in a precharge step section of a circuit which comprises pull-down circuit network section 1223 shown in FIG. 13. FIG. 23 in turn is a configuration which comprises footer section 1215 in the example shown in FIG. 16 in which two precharge step sections form a differential circuit.

While FIG. 20 shows an example which comprises precharge section 121 and predischarge section 122 shown in FIG. 4, the precharge section and predischarge section shown in FIG. 12 or FIG. 15 may be employed.

As shown in FIG. 24, dynamic gate section 12 may comprise high-level holding section 1216 for holding an output voltage of precharge step section 121 at high level when the supply of the clock for power gating is stopped, and may comprise low-level holding section 1226 for holding the output voltage of predischarge step section 122 at low level when the supply of the clock for power gating is stopped.

While FIG. 24 shows an example which comprises high-level holding section 1216 at the output of precharge section 121 shown in FIG. 4, and low-level holding section 1226 at the output of predischarge section 122 shown in FIG. 4, high-level holding section 1216 may be connected to the output of precharge section 121 shown in FIG. 12 or FIG. 15, and low-level holding section 1226 may be connected to the output of predischarge section 122 shown in FIG. 12 or FIG. 15.

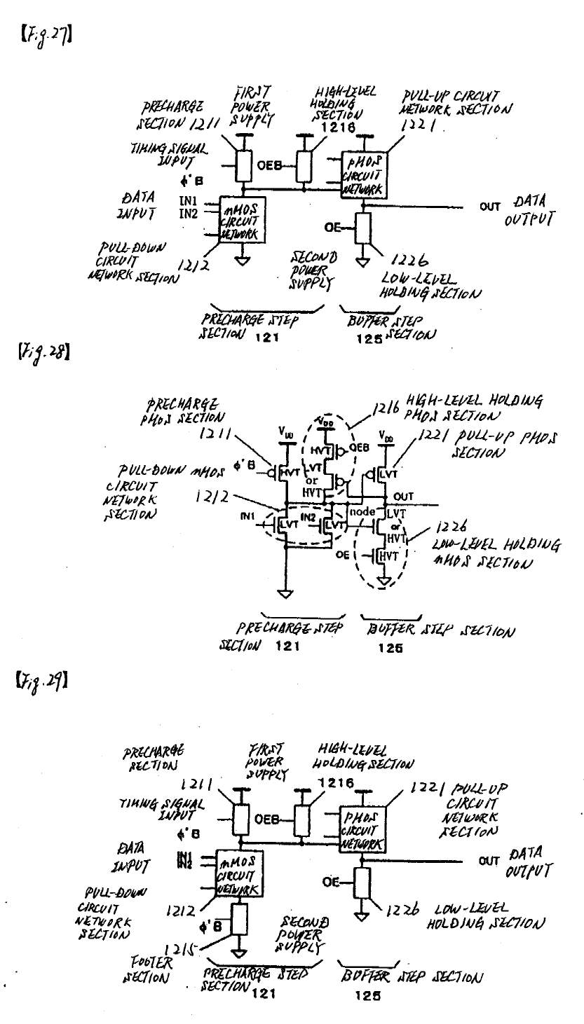

As shown in FIG. 25, high-level holding section 1216 shown in FIG. 24 comprises two pMOSFETs connected in series, where the pMOSFETs are connected between the first power supply and the output terminal of precharge step section 121. From among the two pMOSFETs, a low-leakage element is employed for the pMOSFET connected to the first power supply, and is applied with output enable signal OEB at its gate terminal. On the other hand, from among the two pMOSFETs, a low-leakage element or a high-speed element is employed for the pMOSFET connected to the output terminal, and is applied with the output signal of predischarge step section 122 at its gate terminal.

Low-level holding section 1226 shown in FIG. 24 comprises two nMOSFETs connected in series, where the nMOSFETs are connected between the second power supply and the output terminal of predischarge step section 122. From among the two nMOSFETs, a low-leakage element is employed for the nMOSFET connected to the second power supply, and is applied with output enable signal OE at its gate terminal. On the other hand, from among the two nMOSFETs, a low-leakage element or a high-speed element is employed for the nMOSFET connected to the output terminal, and is applied with the output signal of precharge step section 121 at its gate terminal.

High-level holding section 1216 shown in FIG. 24, in turn, may comprise a pMOSFET and an inverter connected in series between the first power supply and the second power supply, and a pMOSFET connected in parallel with the inverter, as shown in FIG. 26. Low-leakage elements or high-speed elements pMOSFET and nMOSFET are employed for the inverter which is applied with an output signal of precharge step section 121 at its gate terminal. A low-leakage element is employed for the pMOSFET connected in series with the inverter, and is applied with output enable signal OEB at its gate terminal. Also, a low-leakage element or a high-speed element is employed for the pMOSFET connected in parallel with the inverter, and is applied with the output signal of the inverter at its gate terminal.

Low-level holding section 1226 shown in FIG. 24, in turn, may comprise an nMOSFET and an inverter connected in series between the first power supply and the second power supply, and an nMOSFET connected in parallel with the inverter, as shown in FIG. 26. Low-leakage elements or high-speed elements pMOSFET and nMOSFET are employed for the inverter which is applied with the output signal of predischarge step section 122 at its gate terminal. A low-leakage element is employed for the nMOSFET connected in series with the inverter, and is applied with output enable signal OE at its gate terminal. A low-leakage element or a high-speed element is employed for the nMOSFET connected in parallel with the inverter, and is applied with an output signal of the inverter at its gate terminal.

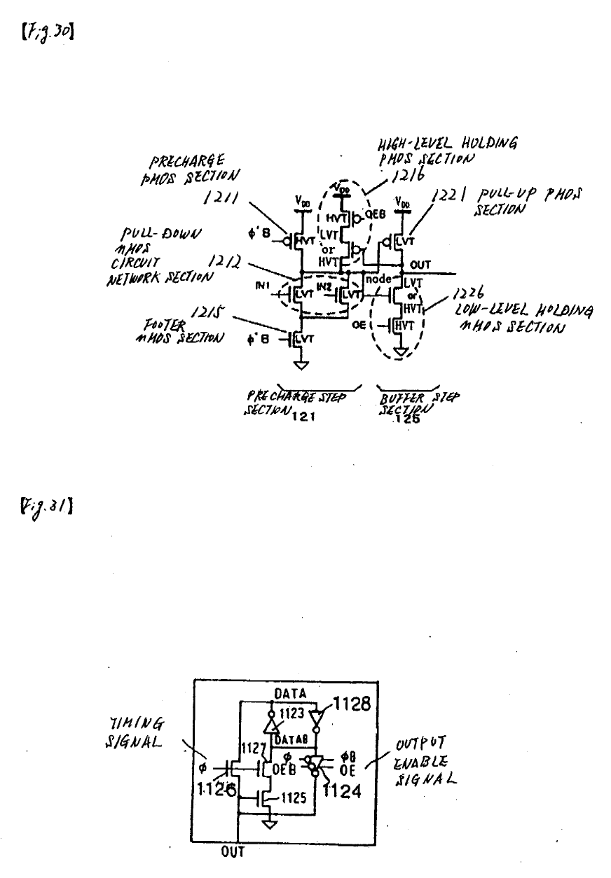

As shown in FIG. 27, dynamic gate section 12 may omit predischarge section 1222 from the configuration shown in FIG. 24. In this event, low-level holding section 1226 receives the output signal of precharge section 1211, and pulls data output OUT down to the low level (second power supply voltage). FIG. 28 is a circuit diagram showing a specific example of the dynamic gate section shown in FIG. 27. Low-level holding section 1226 comprises two nMOSFETs connected in series, where the nMOSFETS are connected between the second power supply and data output OUT.

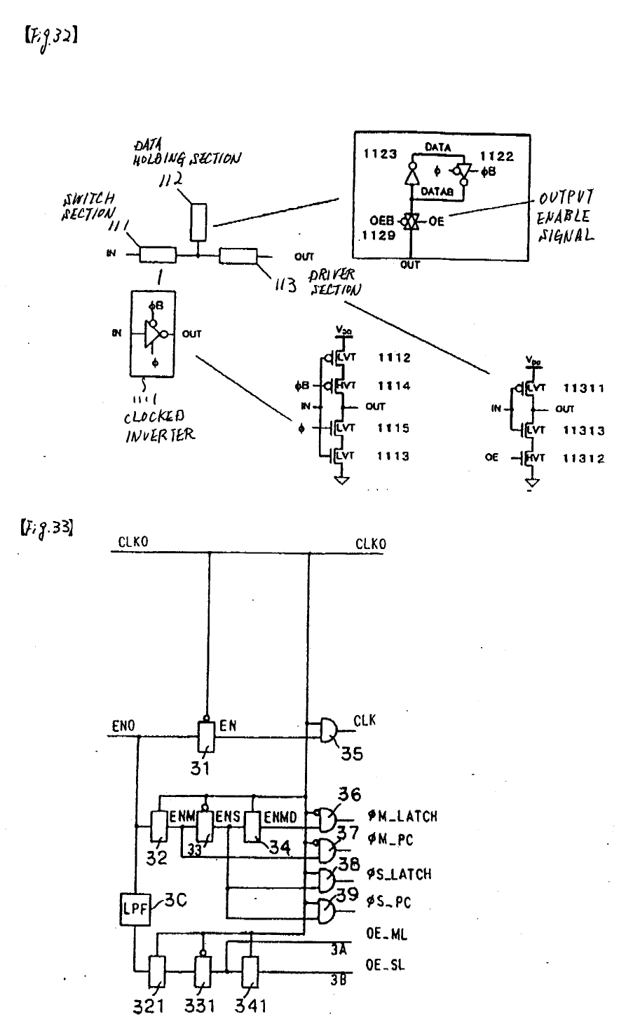

Alternatively, dynamic gate section 12 may comprise footer section 1215 in predischarge step section 121 shown in FIG. 27, as shown in FIG. 29. In such a configuration, even if data input to pull-down nMOSFET circuit network section 1212 is instable, the precharge operation is possible. FIG. 30 is a circuit diagram showing a specific example of the dynamic gate section shown in FIG. 29. A high-speed element nMOSFET can be employed for footer section 1215 contained in the dynamic gate section shown in FIG. 29, as shown in FIG. 30.

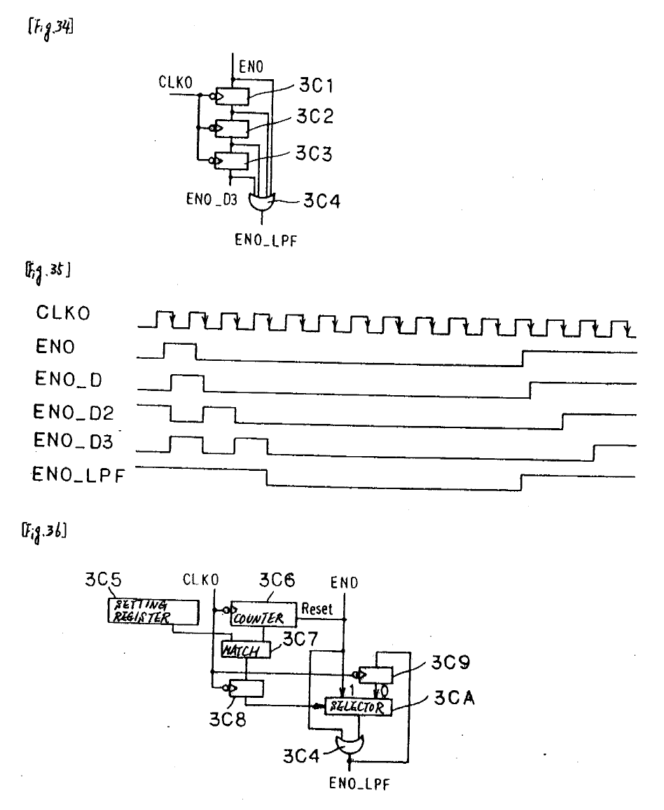

As shown in FIG. 31, data holding section 112 shown in FIG. 5 may comprise inverter 1123 and inverter 1128 which have their input terminals and output terminals connected to each other; an inverter and clocked enabled inverter 1124 which have their input terminals and output terminals connected to each other; and nMOSFET 1126 connected in parallel with inverter 1128 and clocked enabled inverter 1124 connected in series. Timing signals φ, φB and enable signals OE, OEB, as described above, control the ON/OFF status of clocked enabled inverter 1124.

The inverter to which clocked enabled inverter 1124 and input/output terminals are connected comprises pMOSFET 1127 and nMOSFET 1125 connected in series, where pMOSFET 1127 has a drain connected to an input terminal of clocked enabled inverter 1124, and nMOSFET 1125 has a source connected to the second power supply. Timing signal φ is applied to the gate of pMOSFET 1127 and to the gate of nMOSFET 1126, and an output signal of data holding section 112 is applied to the gate of nMOSFET 1125.

As shown in FIG. 32, latch section 11 may comprise driver section 113 in addition to the configuration shown in FIG. 5. Driver section 113 comprises an inverter and nMOSFET1 (nMOS switch) 1312 connected in series between the first power supply and the second power supply. In such a configuration, since a load connected to the output is driven by driver section 113, the size of a transistor included in driver section 113 can be readily optimized. Also, since a load on data holding section 112 is established by comprising driver section 113, transfer gate 1129 may be used for data holding section 112, for example, by taking into consideration noise margin or the like (see FIG. 32). Further, since the operation of data holding section 112 becomes stable, the logic of data held in data holding section 112 will not invert. Transfer gate 1129 is connected to an input terminal of inverter 1123 and to an output terminal of clocked inverter 1122, and turns on or off the input/output of data in accordance with output enable signals (OE, OEB).

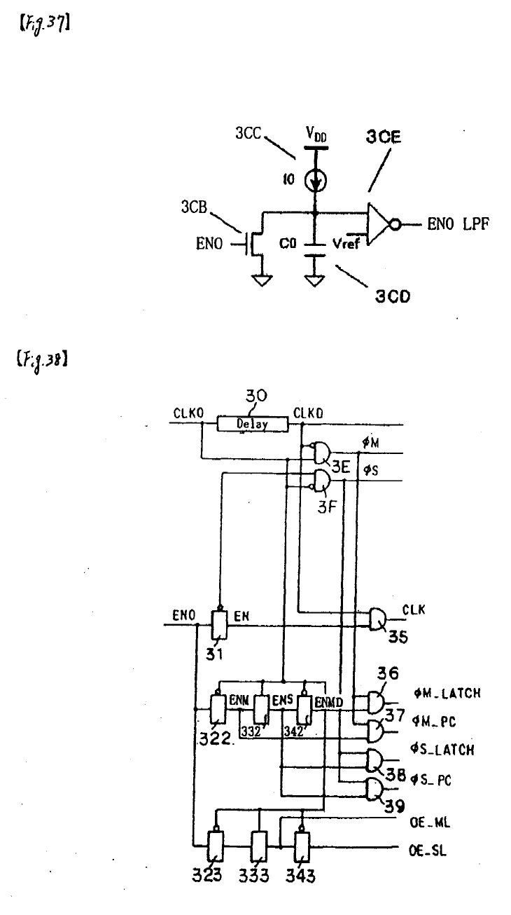

As shown in FIG. 33, timing signal generating section 3 may comprise high through latch circuit 321, low through latch circuit 331, high through latch circuit 341, and low pass section 3C, in addition to the circuit shown in FIG. 6. High through latch circuit 321, low through latch circuit 331, and high through latch circuit 341 are connected in series, and are respectively applied with clock CLK0. Clock enable signal EN0 is supplied to an input terminal of high through latch circuit 321 through low pass section 3C. In the configuration shown in FIG. 33, an output signal of high through latch circuit 341 serves as master step latch hold data output enable signal OE_ML, while an output signal of low through latch circuit 331 serves as slave step latch hold data output enable signal OE_SL. These signals are used to control the operation of high-level holding section 1216, low-level holding section 1226, pull-up section 1224, and pull-down section 1214 included in master step section 1 and slave step section 2.

As shown in FIG. 34, low pass section 3C shown in FIG. 33 comprises three flip-flops 3C1-3C3 connected in series, and OR circuit 3C4, where clock CLK0 is supplied to flip-flops 3C1-3C3, respectively. In this regard, the number of the flip-flops need not be three, but may be any number.

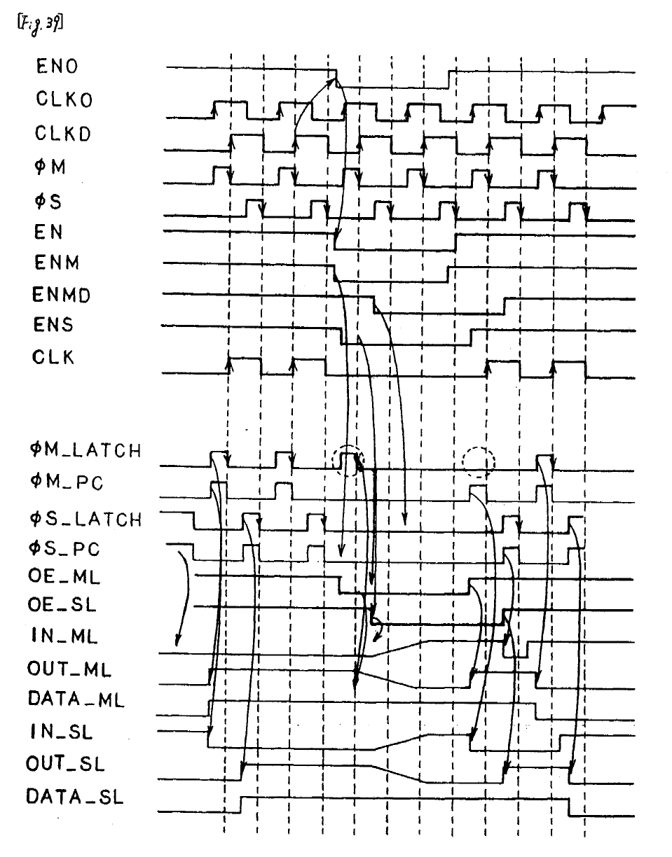

FIG. 35 is a timing chart showing the operation of the low pass section shown in FIG. 33.

As shown in FIG. 35, low pass section 3C shown in FIG. 34 outputs a logical OR result EN0_LPF between clock enable signal EN0 and clock enable signal EN0 of the previous state in two or more cycles.

Using such an output of low pass section 3C, a delay occurs in disabling master step latch hold data output enable signal OE_ML and in slave step latch hold data output enable OE_SL, but a change in clock enable signal EN0 can be restrained. Accordingly, the influence can be reduced when clock enable signal EN0 frequently changes.

Also, low pass section 3C shown in FIG. 33 may comprise, as shown in FIG. 36, counter 3C6 for counting the clock number of clock CLK0 (counting zero); setting resister 3C5 for storing a previously set threshold; match detector 3C7 for comparing a counter value with the value stored in the setting register 3C5; latch circuit 3C8 for holding the comparison result of match detector 3C7; selector 3CA for outputting clock enable signal EN0 when the counter value is equal to the set value, and for outputting clock enable signal EN0_LPF of the previous state in one clock cycle when the counter value is smaller than the set value, depending on the comparison result of match detector 3C7; OR circuit 3C4 for outputting logical OR of the output signal of selector 3CA and clock enable signal EN0; and latch circuit 3C9 for holding an output signal of OR circuit 3C4 and for supplying the clock enable signal of the previous state in one clock cycle to selector 3CA.

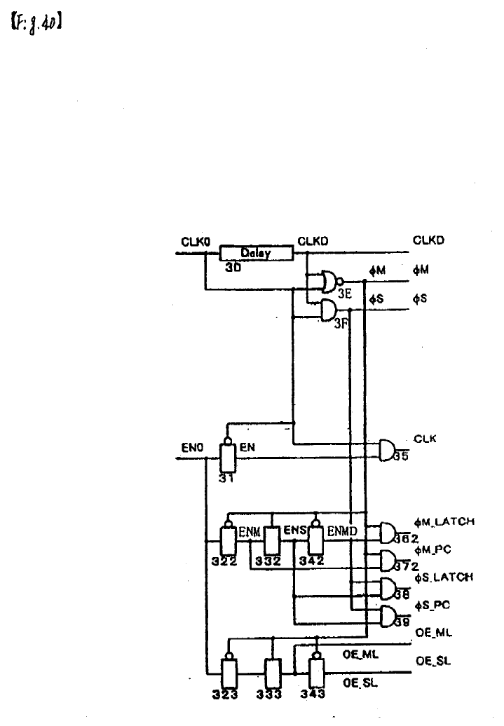

Alternatively, as shown in FIG. 37, low pass section 3C shown in FIG. 33 may comprise reset circuit 3CB which comprises an nMOSFET to which clock enable signal EN0 is applied; current source 3CC for generating current I0 in proportion to a leakage current of an intended circuit; capacitor 3CD comprising load capacitance C0 in proportion to an overhead which occurs in the power gating using the clock enable signal; and comparator 3CE for comparing predetermined reference voltage Vref with an output voltage of capacitor 3CD. Generally, a leakage current of a circuit is largely affected by variations in device characteristics and changes in temperature, thus causing unnecessary power gating. As such, the unnecessary power gating due to frequent changes in clock enable signal EN0 can be eliminated by providing low pass section 3C shown in FIG. 37. Using low pass section 3C shown in FIG. 37, an efficient adaptive control can be realized in units of clock cycles by a combination of a dynamic gate capable of fast return within one clock cycle having a data holding function of capacitor 3CD.

As shown in FIG. 38, timing signal generating section 3 may comprise high through latch circuit 323, low through latch circuit 333, high through latch circuit 343, delay circuit 3D, 2-input AND circuit 3E, and 2-input AND circuit 3F, in addition to the circuit shown in FIG. 6. High through latch circuit 323, low through latch circuit 333, and high through latch circuit 343 are connected in series, and are supplied with clock CLK0, respectively. An input terminal of high through latch circuit 323 is supplied with clock enable signal EN0. In the configuration shown in FIG. 33, an output signal of high through latch circuit 343 serves as slave step latch hold data output enable signal OE_SL, while an output signal of low through latch circuit 333 serves as master step latch hold data output enable signal OE_ML.

Also, in the circuit shown in FIG. 38, clock CLI0 is delayed by delay circuit 3D, and gated clock CLK is generated by 2-input AND circuit 35 based on clock enable signal EN0 and clock CLK0 output from delay circuit 3D. Low through latch circuit 31 is supplied with clock CLK0, and clock enable signal EN0 is applied to an input terminal.

2-input AND circuits 3E, 3F are applied with clock CLK0 output from delay circuit 3D and clock CLK0, and output pulse signal φM for the master step section and pulse signal φS for the slave step section.

Input AND 36 is applied with output signal ENMD of high through latch circuit 342 and pulse signal φM, and outputs master step latch timing signal φM_LATCH. 2-input AND circuit 37 is applied with output signal ENM of high through latch circuit 322 and pulse signal φM, and outputs master step precharge timing signal φM_PC. 2-input AND circuit 38 is applied with output signal ENS of low through latch circuit 332 and pulse signal φS, and outputs slave step latch timing signal φS_LATCH. 2-input AND circuit 39 is applied with output signal ENS of low through latch circuit 332 and pulse signal φS, and outputs slave step precharge timing signal φS_PC.

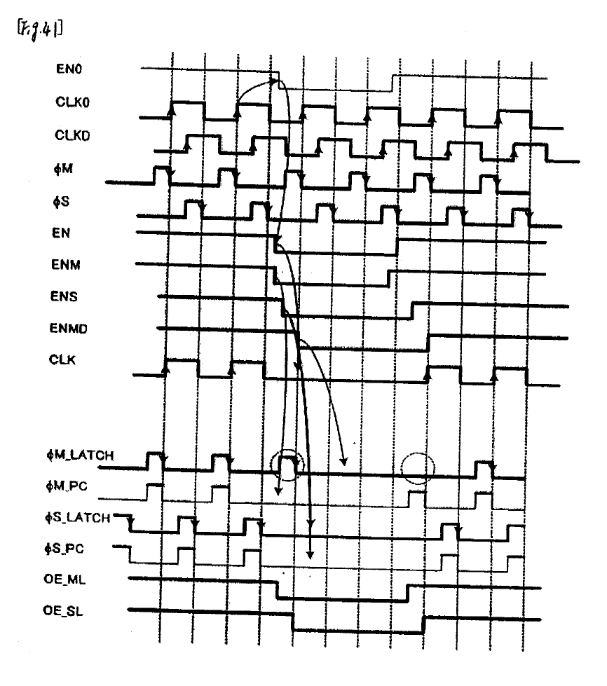

In such a configuration, as shown in FIG. 39, a latch timing of clock enable signal EN0 by low through latch circuit 31, which differs from the timing signal generating section shown in FIG. 6, is not at a falling timing of clock CLK0 but at a rising timing of clock CLK0. Therefore, as clock enable signal EN0 changes from 1 to 0, the supply of gated clock CLK stops from that period. On the other hand, as clock enable signal EN0 changes from 0 to 1, the supply of gated clock CLK is resumed from that period. In this regard, FIG. 39 shows an example in which clock CLK0 is delayed by a quarter period from clock CL0 by delay circuit 3D. The supply/stop of gated clock CLK can also be delayed by one-half period of clock CLK0 or more by clock enable signal EN0.

Also, high through latch circuit 323 may be applied with the clock enable signal through the low pass section in a manner similar to timing signal generating section 3 shown in FIG. 33. In this event, the latch timing becomes inverted with respect to clock CLK0.

Timing signal generating section 3 shown in FIG. 38 is configured to operate with reference to the rising of CLK0 which is a delayed version of clock CLK0, but timing signal generating section 3 may be configured to operate with reference to the rising of clock CLK0 as shown in FIG. 40. In the configuration shown in FIG. 40, the pulse widths of pulse signal φM and φS are not determined by the delay amount of delay circuit 3D, but by the period of clock CLK0 minus the delay amount of delay circuit 3D, as shown in FIG. 41. Generally, when pulse signal φM and φS generated by timing signal generating section 3 are supplied as they are to each master step section 1 and slave step section 2, it is difficult to match the pulse widths and phase relationship because they are high-speed signals. For this reason, pulse signals φM and φS are not distributed to each master step section 1 and slave step section 2, but pulse signals φM and pulse signal φS are preferably generated in each master step section 1 and slave step section 2 with reference to clock CLK0. The configuration shown in FIG. 40 is an example suitable for generating pulse signal φM and pulse signal φS in each master step section 1 and slave step section 2.

In timing signal generating section 3 shown in FIG. 40, pulse signal φM is generated using 2-input NOR circuit 3E instead of 2-input AND circuit 3E shown in FIG. 38, and pulse signal φS is generated by 2-input AND circuit 3F instead of 2-input AND circuit 3F shown in FIG. 38. Gated clock CLK in turn is generated by 2-input AND circuit 35 based on clock enable signal EN and clock CLK0. Outputs of master step latch timing signal φM_LATCH, master step precharge timing signal φM_PC, slave step latch timing signal φS_LATCH, and slave step precharge timing signal φS_PC are controlled by pulse signal φM in a manner similar to timing signal generating section 3 shown in FIG. 38.

1. A dynamic semiconductor device comprising:
a plurality of master step sections each including a latch section for temporarily holding input data, and a dynamic gate section applied with a timing signal different from said latch section and capable of reducing leakage current during operation through power gating;
a plurality of slave step sections alternately connected with said master step sections, each comprising said latch section and said dynamic gate section; and
a timing signal generating section for generating signals for controlling the operation of said master step sections and said slave step sections, respectively, based on a clock enable signal and a clock used in the power gating,
wherein said timing signal generating section supplies said latch section with a signal for holding data at a previous step before the data is erased.

2. A dynamic semiconductor device comprising:
a plurality of master step sections each including a latch section for temporarily holding input data, and a dynamic gate section applied with a timing signal different from said latch section and capable of reducing leakage current during operation through power gating;
a plurality of slave step sections alternately connected with said master step sections, each comprising said dynamic gate section; and
a timing signal generating section for generating signals for controlling the operation of said master step sections and said slave step sections, respectively, based on a clock enable signal and a clock used in the power gating,
wherein said timing signal generating section supplies said latch section with a signal for holding data at a previous step before the data is erased.

3. The dynamic semiconductor device according to claim 2, wherein said dynamic gate section comprises:
a precharge step section including a precharge section which becomes turned on or off in accordance with the timing signal, and a pull-down circuit network section for outputting a logical operation result of input data; and
a predischarge step section including a predischarge section which becomes turned on or off in accordance with the timing signal, and a pull-up circuit network section for outputting a logical operation result of data output from said precharge step section.

4. The dynamic semiconductor device according to claim 2, wherein said dynamic gate section comprises:
a precharge step section including a precharge section which becomes turned on or off in accordance with the timing signal, and a pull-up circuit network section and a pull-down circuit network section for outputting a logical operation result of input data; and
a predischarge step section including a predischarge section which becomes turned on or off in accordance with the timing signal, and a pull-down circuit network section and a pull-down circuit network section, respectively, for outputting a logical operation result of data output from said precharge step section.

5. The dynamic semiconductor device according to claim 2, wherein said dynamic gate section comprises:
a precharge step section including two precharge sections which becomes turned on or off in accordance with the timing signal, and two pull-down circuit network sections for outputting a logical operation result of two complementary data signals input thereto; and
a predischarge step section including two predischarge sections which becomes turned on or off in accordance with the timing signal, and two pull-up circuit network sections for outputting a logical operation result of data output from said precharge step section.

6. The dynamic semiconductor device according to claim 2, wherein said dynamic gate section comprises:
a precharge step section including two precharge sections which becomes turned on or off in accordance with the timing signal, and two pull-up circuit network sections and a pull-down circuit network section for outputting a logical operation result of two complementary data signals input thereto; and
a predischarge step section including two predischarge sections which becomes turned on or off in accordance with the timing signal, and two pull-down circuit network sections and a pull-up circuit network section for outputting a logical operation result of data output from said precharge step section.

7. The dynamic semiconductor device according to claim 3, wherein said dynamic gate section comprises:
a pull-down section for pulling down an output terminal of said precharge step section.

8. The dynamic semiconductor device according to claim 3, wherein said dynamic gate section comprises:
a pull-up section for pulling up an output terminal of said predischarge step section.

9. The dynamic semiconductor device according to claim 2, wherein said dynamic gate section comprises:
a precharge step section including a precharge section which becomes turned on or off in accordance with the timing signal, and a pull-down circuit network section for outputting a logical operation result of data input thereto;
a pull-down section for pulling down an output terminal of said precharge step section; and
a buffer step section comprised of an inverter which is applied with data output from said precharge step section.

10. The dynamic semiconductor device according to claim 2, wherein said dynamic gate section comprises:
a predischarge step section including a predischarge section which becomes turned on or off in accordance with the timing signal, and a pull-up circuit network section for outputting a logical operation result of data input thereto;
a pull-up section for pulling up an output terminal of said predischarge step section; and
a buffer step section comprised of an inverter which is applied with data output from said predischarge step section.

11. The dynamic semiconductor device according to claim 2, wherein said dynamic gate section comprises:
a precharge step section including two precharge sections which becomes turned on or off in accordance with the timing signal, and two pull-down circuit network sections for outputting a logical operation result of two complementary data signals input thereto;
two pull-down sections for pulling down output terminals of said precharge step section, respectively; and
two buffer step sections comprised of inverters, each of which is applied with data output from said precharge step section.

12. The dynamic semiconductor device according to claim 2, wherein said dynamic gate section comprises:
a predischarge step section including two predischarge sections which becomes turned on or off in accordance with the timing signal, and two pull-up circuit network sections for outputting a logical operation result of two complementary data signals input thereto;
a pull-up section for pulling up an output terminal of said predischarge step section; and
buffer step section comprised of an inverter which is applied with data output from said predischarge step section.

13. The dynamic semiconductor device according to claim 3, wherein said dynamic gate section further comprises:
a footer section for turning off a power supply to said pull-down circuit network section when said precharge section turns on.

14. The dynamic semiconductor device according to claim 3, wherein said dynamic gate section further comprises:
a header section for turning off a power supply to said pull-up circuit network section when said predischarge section becomes turned on.

15. The dynamic semiconductor device according to claim 2, wherein said dynamic gate section further comprises:
a high-level holding section for holding an output voltage of said precharge step section at a high level when the clock is not supplied for the power gating.

16. The dynamic semiconductor device according to claim 2, wherein said dynamic gate section further comprises:
a low-level holding section for holding an output voltage of said predischarge step section at a low level when the clock is not supplied for the power gating.

17. The dynamic semiconductor device according to claim 2, wherein said latch section comprises a switch section and a data holding section,
wherein said data holding section latches data input thereto when said switch section becomes turned on, and said data holding section continues to hold the data when said switch section becomes turned off.

18. The dynamic semiconductor device according to claim 17, wherein said latch section further comprises:
a driver section for driving a load connected on an output side in accordance with data held by said data holding section.

19. The dynamic semiconductor device according to claim 17, wherein said switch section is a clocked inverter for turning on or off data output in accordance with a signal at a predetermined period.

20. The dynamic semiconductor device according to claim 17, wherein said data holding section comprises:
an inverter having an input terminal and an output terminal connected to each other, and a clocked inverter for turning on or off data output in accordance with the timing signal; and
a clocked inverter having an input terminal and an output terminal connected to each other, and a clocked enabled inverter for turning on or off data output in accordance with the timing signal, and an enable signal for the power gating which is synchronized with a supply/stop of the clock.

21. The dynamic semiconductor device according to claim 17, wherein said data holding section comprises:
an inverter having an input terminal and an output terminal connected to each other, and a clocked inverter for turning on or off data output in accordance with the timing signal; and
a transfer gate connected to the input terminal of said inverter and to an output terminal of said clocked inverter for turning on or off data input/output in accordance with an enable signal for the power gating which is synchronized with a supply/stop of the clock.

22. The dynamic semiconductor device according to claim 18, wherein said driver section comprises:
an inverter and an nMOS switch connected in series between said inverter and a ground potential.

23. The dynamic semiconductor device according to claim 3, wherein said timing signal generating section:
generates a signal for causing said latch section of said master step section to transition to a clock stop state after holding data when the clock enable signal goes to 0; and
generates a signal for outputting data held by said latch section of said master step section and for turning on said precharge section and said predischarge section included in said dynamic gate section in said master step section when the clock enable signal goes to 1.

24. The dynamic semiconductor device according to claim 15, wherein said timing signal generating section:
controls said high-level holding section, said low-level holding section, said pull-up section, and said pull-down section, respectively, with a signal generated from the clock enable signal, and a clock enable signal of the previous state in two or more cycles.

25. The dynamic semiconductor device according to claim 15, wherein said timing signal generating section comprises:
a low pass section for restraining a change in the clock enable signal.

26. The dynamic semiconductor device according to claim 3, wherein said timing signal generating section outputs a latch signal supplied to said latch section of said master step section for latching data input thereto with a delay equal to one cycle of the clock from a timing at which said precharge section is turned on.
